(19) United States
(12) Patent Application Publication
(10) Pub. No.: US 2023/0142453 A1
(43) Pub. Date: May 11, 2023

(54) RADIATION-EMITTING COMPONENT, LIGHT SOURCE AND DISPLAY DEVICE

(71) Applicant: ams-OSRAM International GmbH, Regensburg (DE)

(72) Inventors: Dominik BAUMANN, Munich (DE); Markus SEIBALD, Kaufering (DE); Stefan LANGE, Augsburg (DE); Frank JERMANN, Koenigsbrunn (DE)

(21) Appl. No.: 17/917,570

(22) PCT Filed: Apr. 1, 2021
(86) PCT No.: PCT/EP2021/058570

§ 371 Date: Oct. 7, 2022

(30) Foreign Application Priority Data
Apr. 9, 2020 (DE) 10 2020 204 649.2

(51) Int. Cl. H01L 33/50

(52) U.S. Cl. CPC H01L 33/504; H01L 33/505; H01L 33/507

(57) ABSTRACT

A radiation-emitting component may include a semiconductor chip and a conversion element. The semiconductor chip may be configured to emit electromagnetic radiation in a first wavelength range in the blue spectral region. The conversion element may have a first luminophore and a second luminophore. The first luminophore may be configured to emit electromagnetic radiation in the first wavelength range to electromagnetic radiation in a second wavelength range in the green spectral region. The second luminophore may be configured to convert at least electromagnetic radiation in the first wavelength range to electromagnetic radiation of a third wavelength range in the red spectral region. The second luminophore may have an excitation spectrum having a maximum ranging from 430 nm to 550 nm inclusive

### CROSS-REFERENCE TO RELATED APPLICATIONS

The present application is a national stage entry according to 35 U.S.C. §371 of PCT application No.: PCT/EP2021/058570 filed on Apr. 1, 2021; which claims priority to German patent application DE 10 2020 204 649.2, filed on Apr. 9, 2020; all of which are incorporated herein by reference in their entirety and for all purposes.

### TECHNICAL FIELD

A radiation-emitting component, a light source and a display device are specified.

### BACKGROUND

One problem addressed is that of providing a radiation-emitting component having improved properties. Further problems addressed are those of providing a light source and a display device having improved properties.

### SUMMARY

A radiation-emitting component is specified. This has a semiconductor chip which, in operation, emits electromagnetic radiation in a first wavelength range in the blue spectral region.

The radiation-emitting component is thus a component that emits electromagnetic radiation in operation. For example, the radiation-emitting component is a light-emitting diode (LED).

The semiconductor chip may comprise an active layer sequence containing an active region which, in operation of the component, can generate the electromagnetic radiation of the first wavelength range, also called primary radiation. The semiconductor chip is, for example, a light-emitting diode chip or a laser diode chip. The primary radiation which is generated in the semiconductor chip may be emitted through a radiation exit surface of the semiconductor chip. The primary radiation may form a beam path or follow a beam path.

“Blue spectral region” here and hereinafter is understood to mean visible light, more particularly in the wavelength range from 430 nm to 500 nm inclusive. The expressions “electromagnetic radiation of a first wavelength range in the blue spectral region” and “blue light” are used synonymously here and hereinafter.

In at least one embodiment, the radiation-emitting component further comprises a conversion element.

A conversion element here and hereinafter is understood to mean a component which, in operation of the component, converts the primary radiation emitted by the semiconductor chip at least partly to a secondary radiation. This process is also referred to as radiation conversion or conversion. The secondary radiation differs here at least partly from the primary radiation and may especially be longer-wave than the primary radiation.

The conversion element is especially disposed in the beam path of the primary radiation in such a way that at least some of the primary radiation hits the conversion element.

In at least one embodiment, the conversion element comprises a first luminophore that converts electromagnetic radiation in the first wavelength range to electromagnetic radiation in a second wavelength range in the green spectral region. The conversion element thus at least partly converts the primary radiation to a secondary radiation comprising wavelengths in the green spectral region.

“Green spectral region” here and hereinafter is understood to mean visible light, more particularly in the wavelength range from 490 nm to 590 nm inclusive, especially greater than 500 nm to 590 nm inclusive. The expressions “electromagnetic radiation in a second wavelength range in the green spectral region” and “green light” are used synonymously here and hereinafter.

In at least one embodiment, the conversion element further comprises a second luminophore that converts at least electromagnetic radiation in the first wavelength range to electromagnetic radiation in a third wavelength range in the red spectral region.

“Red spectral region” here and hereinafter is understood to mean visible light, more particularly in the wavelength range from 590 nm to 700 nm inclusive, especially greater than 590 nm to 700 nm inclusive. The expressions “electromagnetic radiation in a third wavelength range in the red spectral region” and “red light” are used synonymously here and hereinafter.

The radiation-emitting component can thus emit mixed light composed of light in the first, second and third wavelength ranges. The mixed light is especially white light.

In at least one embodiment, the second luminophore has an excitation spectrum having a maximum between 430 nm and 550 nm inclusive.

The second luminophore thus has an absorption maximum or absorption band in the blue spectral region and is thus of good suitability for use in a radiation-emitting component with blue light as primary radiation. As well as the maximum in the range between 430 nm and 550 nm, the second luminophore may have further maxima in its excitation spectrum, for example in the near UV region, for example in the range between 320 nm and 420 nm inclusive.

In at least one embodiment, a radiation-emitting component is specified, comprising
a semiconductor chip which, in operation, emits electromagnetic radiation in a first wavelength range in the blue spectral region, and
a conversion element having a first luminophore that converts electromagnetic radiation in the first wavelength range to electromagnetic radiation in a second wavelength range in the green spectral region,
and having a second luminophore that converts at least electromagnetic radiation in the first wavelength range to electromagnetic radiation in a third wavelength range in the red spectral region,
wherein the second luminophore has an excitation spectrum having a maximum between 430 nm and 550 nm inclusive.

In the radiation-emitting component, a blue light-emitting semiconductor chip is thus combined with a green light-emitting first luminophore and a red light-emitting second luminophore.

The second luminophore here has long-wave absorption and excitability. This means that controlled absorption, for example, of blue-green and/or cyan light of the primary radiation is possible. On the other hand, the second luminophore emits red light with high luminous efficacy of radiation (LER).

Controlled absorption of blue-green and/or cyan light with simultaneously high LER can be used, for example, in a light source which is employed in order to increase melatonin production in the body.

Light sources, as well as their illumination function, also show an interaction with the human body. Controlled optimization of the emission spectrum of a light source can improve the physiological effect of light on man. For example, a light source can control circadian rhythm, especially by influencing melatonin production. A high proportion of blue-green and/or cyan light in the spectrum of a light source leads to reduced melatonin production, which leads to elevated activity in the body. On the other hand, a low proportion of blue-green and/or cyan light in the spectrum of a light source leads to elevated melatonin production, which leads to reduced activity.

A radiation-emitting component with a low proportion of blue-green and/or cyan light, especially with a spectral gap in the blue-green and/or cyan region, having a high LER with simultaneously good color rendering, can thus especially be used as light source in the evening hours in order to prevent disruption of circadian rhythm.

The proportion of blue-green or cyan light in the emission spectrum of a radiation-emitting component can be described using the parameter MDEF (“melanopic daylight-equivalent efficiency factor of luminous radiation”). The MDEF describes the ratio of the melanopically active proportion of the emission spectrum based on the photopically assessed illumination level of a radiation-emitting component. Radiation-emitting components with high MDEF, i.e. a high blue-green and/or cyan component in the spectrum, lead to elevated activity; radiation-emitting components having low MDEF, i.e. a low blue-green and/or cyan component in the spectrum, lead to reduced activity.

Conventionally, light sources with low color temperature (CCT) are frequently used in the evening hours. Such light sources are “warm white”, i.e. are typically rich in orange-red hues and show a relatively low proportion of blue-green and/or cyan hues by comparison with light sources having high CCT (“cold white”) . Thus, light sources having low CCT achieve lower MDEF values than those having high CCT. CCT and MDEF are thus coupled to one another and can frequently be adjusted independently of one another only to an insufficient degree.

However, use of the second luminophore having the abovementioned properties in the radiation-emitting component can achieve a significant reduction in MDEF with simultaneously unchanged color temperature CCT, especially also with achievement of high color quality (measured as CRI, R9) and high luminous efficacy of radiation (LER).

Controlled absorption of blue-green and/or cyan light with simultaneously high LER may secondly also be advantageous when the radiation-emitting component is used as display backlighting.

In displays, for example liquid-crystal (LC) displays, color filters ensure the separation of the white light emitted by a radiation-emitting component, for example an LED, into the colors red, green and blue for the respective pixels or color channels.

Use of luminophores having broad emission results in “crosstalk”, in which even red light, for example, can get into the green color channel to some degree. This ultimately leads to a reduction in the maximum color space that can be presented by the display. Such an effect can be partly reduced by color filters having narrower spectral transmission windows, but only at the expense of total brightness and hence the efficiency of the display.

The size of the color space that a display can cover thus depends on the emission spectrum, especially the white light spectrum of the display backlighting. There exist various standardized color space definitions that are each defined by primary coordinates for the “blue”, “green” and “red” corners, especially by the coordinates thereof in the CIE-xy color space or CIE-u'v′ color space. Examples of color spaces having high color quality, i.e. high color saturation of the vertices and a wide range of maximum presentable colors, are sRGB, NTSC, AdobeRGB, DCI P3 and rec2020. DCI P3 in particular is a technically important standard which is in common use in the field of high-quality displays.

In the case of the radiation-emitting component described here, the emission maxima of the first and second luminophores are optimized such that, in combination with the absorption curves and transmission curves of color filters in a display device, high color space coverage can be achieved with elevated LER compared to conventional display devices.

In at least one embodiment, the second luminophore has an emission spectrum having an emission maximum having a half-height width between 1 nm and 10 nm inclusive, especially between 1 nm and 5 nm inclusive.

The emission spectrum of the second luminophore may have a multitude of emission peaks, with the peak having the highest intensity being referred to as emission maximum. In at least one embodiment, the emission spectrum of the second luminophore has a multitude of emission peaks, with at least one emission peak having a half-height width between 1 nm and 10 nm inclusive, especially between 1 nm and 5 nm inclusive.

The low half-height width of the emission maximum is thus a narrowband emission of the second luminophore, which can also be referred to as line emission. The measured half-height width of the emission maximum may also depend here on the resolution and accuracy of the measurement method used. Narrowband emission especially contributes to emission of red light with high luminous efficacy of radiation (LER).

In at least one embodiment, the excitation spectrum of the second luminophore has a maximum in the range between 470 nm and 510 nm inclusive. The second luminophore thus has long-wave absorption and excitability and can thus be used efficiently in order to provide a radiation-emitting component having greatly reduced MDEF coupled with simultaneously high color temperature, color quality and luminous efficacy of radiation. On the other hand, such a second luminophore is also of good suitability for radiation-emitting components that are used as display backlighting.

In at least one embodiment, the emission maximum of the second luminophore is in the range between 620 nm and 635 nm inclusive, especially between 625 nm and 633 nm inclusive. For example, the emission maximum is at 628 nm. Thus, the second luminophore emits in the red to deep red region in conjunction with long-wave absorption and excitability and low half-height width of the emission maximum.

In at least one embodiment, the second luminophore, especially in operation of the component, at least partly converts electromagnetic radiation in the second wavelength range to electromagnetic radiation in the third wavelength range. More particularly, the second luminophore absorbs wavelengths in the blue-green and/or cyan region of the second wavelength range. Thus, the blue-green or cyan component of the light emitted by the radiation-emitting component is reduced even further.

In at least one embodiment, the second luminophore has the general formula A_{z}EₑX₆:RE where
A is selected from the group of divalent elements,
E is selected from the group of tetravalent elements,
X is selected from the group of monovalent elements,
RE is selected from activated elements,
0.9 ≤ z ≤ 1.1 and
0.9 ≤ e ≤ 1.1.

The elements present in the empirical formula A_{z}EₑX₆:RE are in charged form, even though this is not stated explicitly. In addition, the empirical formula A_{z}EₑX₆:RE may include further elements, for example in the form of impurities. Taken together, these impurities are at most 5 mol%, especially at most 1 permille, for example not more than 100 ppm (parts per million), such as not more than 10 ppm.

In the present context, the term “valency” in relation to a particular element means how many elements having a single opposite charge are required in a chemical compound to achieve balancing of charge. Thus, the term “valency” comprehends the charge value of the element.

The second luminophore of the empirical formula A_{z}EₑX₆:RE may be outwardly uncharged or in a formal sense, to a small degree, not have complete balancing of charge.

By comparison with conventionally used red light-emitting luminophores, for example K₂SiF₆:Mn (also KSF hereinafter), the light yield or luminous efficiency of the present second luminophore having the empirical formula A_{z}EₑX₆:RE is elevated on account of its low spectral half-height width and the short-wave shift in emission. The present luminophore also has a high luminous efficacy of radiation or photometric radiation equivalent (LER). In at least one embodiment, the second luminophore has an LER of greater than 190 lmW⁻¹. For example, the LER of the second luminophore is greater than 202.7 lmW⁻¹.

In at least one embodiment, A is selected from Ca, Sr, Ba, Zn, Mg or combinations thereof. In at least one embodiment, A comprises or consists of Ca, Sr or Zn. In at least one embodiment, E is selected from Hf, Ti, Zr, Pb or combinations thereof. In at least one embodiment, E consists of Hf, Ti or Zr. In at least one embodiment, X is selected from F, Cl, Br, I or combinations thereof. In at least one embodiment, X comprises or consists of F. In at least one embodiment, RE is selected from Mn, Cr, Ni or combinations thereof. In at least one embodiment, RE comprises or consists of Mn. The activated elements RE may be tetravalent elements, i.e. with a quadruple positive charge.

In at least one embodiment, the second luminophore is selected from CaHfF₆:Mn, CaZrF₆:Mn, SrTiF₆:Mn, ZnHfF₆:Mn and combinations thereof. These materials have an efficiency advantage and simultaneously improved color rendering compared to conventional red light-emitting luminophores. For example, the emission maximum of the luminophores CaZrF₆:Mn and CaHfF₆:Mn is at a wavelength λₘₐₓ of about 628.3 nm. For example, the emission maximum of the luminophore SrTiF₆:Mn is at a wavelength λₘₐₓ of about 628.4 nm. For example, the emission maximum of the luminophore ZnHfF₆:Mn is at a wavelength of about 632.7 nm. For example, the luminous efficacy of radiation of the luminophore CaZrF₆:Mn is about 222.2 lmW⁻¹. For example, the luminous efficacy of radiation of the luminophore CaHfF₆:Mn is about 219.3 lmW⁻¹. For example, the luminous efficacy of radiation of the luminophore SrTiF₆:Mn is about 190.7 lmW⁻¹. For example, the luminous efficacy of radiation of the luminophore ZnHfF₆:Mn is about 194.9 lmW⁻¹.

The second luminophore may have a dominant wavelength (λ_{dorn}) between 610 nm and 618 nm inclusive. The dominant wavelength is the wavelength of monochromatic light that generates a similar perception of color to the polychromatic radiation to be described. In general, the dominant wavelength differs from the emission maximum. In particular, the dominant wavelength of the second luminophore after excitation with a primary radiation in the blue spectral region is between 610 nm and 618 nm inclusive. The dominant wavelength of the second luminophore may be between 612.7 nm and 617.7 nm inclusive. For example, the dominant wavelength of the second luminophore CaZrF₆:Mn is at a dominant wavelength λ_{dom} of about 615.4 nm. For example, the dominant wavelength of the second luminophore CaHfF₆:Mn is at a dominant wavelength λ_{dom} of about 617.2 nm. For example, the dominant wavelength of the second luminophore SrTiF₆:Mn is at a dominant wavelength λ_{dom} of about 612.7 nm. For example, the dominant wavelength of the second luminophore ZnHfF₆:Mn is at a wavelength λ_{dom} of about 617.7 nm.

A second luminophore having the general formula A_{z}EₑX₆:RE can be prepared by a process comprising the following steps:
providing a stoichiometric composition of reactants,
homogenizing the reactants to produce a reaction mixture,
heating the reaction mixture to a maximum temperature.

In the process, the reactants may be selected from a group comprising halides, carbonates, sulfides, oxides, oxalates, imides, permanganates, nitrates, nitrites, sulfates, sulfites, hydrogensulfates, disulfates, thiosulfates, cyanides, cyanates, thiocyanates, acetates, carboxylic acid derivatives, ternary compounds, especially ammonium compounds, and amides of each of A, E, X and RE and combinations thereof. The reactants may be selected from a group comprising halides, carbonates, sulfides, oxides, oxalates, imides and amides of each of A, E, X and RE and combinations thereof.

In addition, the reactants may be selected from a group comprising AX₂, EO₂, ES₂, EOX₂, ACOs and REX₂ and combinations thereof. Alternatively or additionally, the oxides, halides, sulfides and carbonates may be obtained from organic precursor compounds that form the reactants in situ. For example, the oxides may be obtained via the decarboxylation of oxalates or from carbonates.

In addition, the reactants may be selected from a group comprising calcium fluoride, hafnium(IV) oxide, manganese(II) chloride tetrahydrate, zinc chloride, strontium carbonate, titanium(IV) sulfide, zirconyl chloride octahydrate and combinations thereof. In particular, elemental X₂ may be used as reactant for component X.

In the process, the reaction mixture may be heated to a maximum temperature of not more than 1000° C., especially to a maximum temperature of not more than 650° C., such as to a maximum temperature of not more than 450° C.

In the process, the heating may take place in an F₂ stream. In particular, during the heating, up to 100% by volume of F₂ is passed through the reaction mixture. Alternatively, the stream includes F₂ and an inert gas. In a non-limiting embodiment, during the heating, up to 10% by volume of F₂ in an inert gas is passed through the reaction mixture. For example, the inert gas is He, Ne, Kr, Ar, Xe, N₂ or SF₆. It is thus possible to ensure oxidizing conditions. No hydrofluoric acid solution is used in the process. The hazard potential resulting from addition of a hydrofluoric acid solution is accordingly avoided.

The heating in the process may be a dry high-temperature process. This means that no additional solvent or acids are added during the heating. The hazard potential resulting from addition of an acid, especially a hydrofluoric acid solution, is accordingly avoided.

In the process for preparing the second luminophore, the reactants may be homogenized. The resultant reaction mixture of the reactants can then be introduced into a crucible, for example into a corundum boat, and placed in a furnace, especially in a tubular furnace, through which up to 100% by volume of F₂ is being passed.

In addition, the process may comprise stepwise heating of the reaction mixture. What is meant by stepwise heating is that the reaction mixture is heated to at least one intermediate temperature at at least one heating rate, and the reaction mixture is kept at an intermediate temperature with a hold time, before the maximum temperature is attained. The intermediate temperature is especially less than the maximum temperature. In particular, the stepwise heating has two heating rates that may be the same or different.

The intermediate temperature is, for example, between 50° C. and 400° C. inclusive. The whole time is, for example, between one hour and 14 days inclusive. The heating rate is, for example, between 0.05° C. per minute and 5° C. per minute inclusive.

In addition, the heating may comprise at least one cooling step. The cooling step especially follows after a heating rate. In the cooling step, the reaction mixture is cooled down to a minimum temperature in the furnace. The minimum temperature is especially between 20° C. and 50° C. inclusive. After the cooling step, the reaction mixture may be blended and subsequently heated again.

In at least one embodiment of the radiation-emitting component, the semiconductor chip has an emission spectrum having a dominant wavelength λ_{dom} of not more than 460 nm, especially not more than 455 nm. Thus, a short-wave, blue light-emitting semiconductor chip is used in the radiation-emitting component. This has a peak wavelength of 450 nm or less with a dominant wavelength λ_{dom} of 455 nm or less, and hence does not itself make any significant contribution to emission in the blue-green and/or cyan region.

In at least one embodiment, the first luminophore has an excitation spectrum that at least partly overlaps with the emission spectrum of the semiconductor chip.

In at least one embodiment, the first luminophore has an excitation spectrum having a maximum in the range between 445 nm and 455 nm inclusive, especially between 448 nm and 450 nm inclusive. Thus, the first luminophore has particularly good excitability with a semiconductor chip, the emission spectrum of which has a dominant wavelength λ_{dom} of 460 nm or less, especially of 455 nm or less. Such a first luminophore can be used especially efficiently in a radiation-emitting component which is used in a light source which is used in order to increase melatonin production in the body.

In at least one embodiment, the first luminophore has an emission spectrum in the range of 500 nm to 580 nm. In at least one embodiment, the emission spectrum of the first luminophore has a peak wavelength shifted in the direction of shorter wavelengths compared to the peak wavelength of a green light-emitting β-sialon, i.e. an oxynitride with β-Si₃N₄ crystal structure in which Eu is present in the form of a solid solution, and which can be expressed by the formula Si₆₋ₖAlₖOₖN₈₋ₖ:Eu with k > 0.45. With such a first luminophore, it is possible, for example, to cover a large color space when the radiation-emitting component is used as display backlighting.

By using a first luminophore with shorter-wave emission compared to β-sialon in display backlighting, it is possible to move the color locus of the filtered green color channel in the direction of a shorter dominant wavelength, i.e. a less yellowish green. It should be noted here that there should if at all possible be no crosstalk of the luminophore emission from one color channel into an adjacent color channel. More particularly, a luminophore emitting green light of excessive spectral breadth or excessively shifted in the direction of short-wave emission can make emission contributions in the emission spectrum of the radiation-emitting component that are in the transmission region of the blue color channel. This can shift the color locus of the blue color channel in the cyan direction, which in turn reduces the overall gamut of the colors that can be presented. However, this effect does not occur in combination with the above-described second luminophore having an absorption maximum between 430 nm and 550 nm inclusive, especially between 470 nm and 510 nm inclusive, such as between 475 nm and 505 nm inclusive. Instead, this achieves elevated color space coverage.

In at least one embodiment, an emission peak of the emission spectrum of the first luminophore has a half-height width of not more than 50 nm, especially not more than 45 nm. This means that the first luminophore is a narrowband-emitting luminophore. This can be used especially efficiently when the radiation-emitting component is used as display backlighting.

In at least one embodiment, the first luminophore is selected from garnets, β-sialons, orthosilicates and combinations thereof.

In at least one embodiment, the first luminophore includes or consists of at least one garnet. For example, the first luminophore selected is (Y,Lu)₃Al₅O₁₂:Ce, the excitation maximum of which, at about 448 nm to 450 nm, is in the region of peak wavelengths of 450 nm or less of a short-wave blue-emitting semiconductor chip. Also conceivable is the use of Y₃(Al,Ga) ₅O₁₂:Ce as first luminophore. Also conceivable are further modified compositions of the general type (Y, Lu, Gd, Tb) ₃ (Al, Ga, Sc) ₅O₁₂ : Ce, provided that the element composition is chosen such that the primary radiation emitted by the semiconductor chip is absorbed particularly efficiently. Such first luminophores may especially be used in radiation-emitting components that are used as light sources with reduced MDEF.

In at least one embodiment, the first luminophore includes or consists of a β-sialon. This is especially a modified β-sialon, i.e. an oxynitride with β-Si₃N₄ crystal structure in which Eu is present in the form of a solid solution, and which can be expressed by the formula Si₆₋ₖAlₖOₖN₈₋ₖ:Eu with 0 < k ≤ 0.45, such as 0.001 ≤ k ≤ 0.40 (or 0.002 ≤ k ≤ 0.35). In particular, such a first luminophore may have a short-wave shift in emission compared to conventional β-sialons in which k > 0.45. The modification can be effected, for example, by altering the O/N or Si/Al ratio in the β-sialon. Such first luminophores may especially be used efficiently in radiation-emitting components that are used as display backlighting in display devices.

In at least one embodiment, the conversion element is applied in direct contact atop a radiation exit surface of the semiconductor chip.

In at least one embodiment, the conversion element is applied by means of a bonding layer on the radiation exit surface of the semiconductor chip.

In at least one embodiment, the conversion element also contains a matrix material. The matrix material may be selected from glass such as silicate, waterglass or quartz glass, or polymers such as polystyrene, polysiloxane, polysilazane, PMMA, polycarbonate, polyacrylate, polytetrafluoroethylene, polyvinyl, silicone resin, silicone or epoxy resin, or combinations thereof.

In at least one embodiment, the semiconductor chip and the conversion element are disposed in the recess of a housing. In at least one further embodiment, the semiconductor chip and/or the conversion element are at least partly surrounded by an encapsulant.

In at least one further embodiment, the conversion element is part of an encapsulant that surrounds the semiconductor chip, or the conversion element forms the encapsulant that surrounds the semiconductor chip. The semiconductor chip is especially embedded into the conversion element and at least partly surrounded by the conversion element. In at least one embodiment, the encapsulant is disposed in the recess of the housing.

In at least one embodiment, the semiconductor chip and the conversion element are disposed in a recess of a housing, wherein the recess of the housing is filled with an encapsulant that at least partly surrounds the semiconductor chip and the conversion element is disposed on the side of the encapsulant remote from the semiconductor chip.

In at least one embodiment, the semiconductor chip is disposed in the recess of a housing, wherein the recess of the housing is filled with an encapsulant that at least partly surrounds the semiconductor chip and the conversion element is disposed outside the recess of the housing on the side of the encapsulant remote from the semiconductor chip. It is optionally possible for particles such as further luminophores or scattering particles, for example, to be embedded within the encapsulant.

In at least one embodiment, the recess of the housing between the semiconductor chip and the conversion element is free of any encapsulant and/or further layers or components.

In at least one embodiment, the encapsulant has a transparency to electromagnetic radiation, especially the primary radiation, of at least 85%, especially of at least 95%.

In at least one embodiment, the encapsulant comprises a material selected from materials as specified for the matrix material.

Also specified is a light source having a first radiation-emitting component. The radiation-emitting component according to the abovementioned embodiments may be suitable and intended for use in a light source as described here. Features and embodiments that have been detailed solely in conjunction with the radiation-emitting component are also applicable to the light source, and vice versa.

In at least one embodiment, the first radiation-emitting component of the light source comprises
a semiconductor chip which, in operation, emits electromagnetic radiation in a first wavelength range in the blue spectral region, and
a conversion element having a first luminophore that converts electromagnetic radiation in the first wavelength range to electromagnetic radiation in a second wavelength range in the green spectral region,
and having a second luminophore that converts at least electromagnetic radiation in the first wavelength range to electromagnetic radiation in a third wavelength range in the red spectral region,
wherein the second luminophore has an excitation spectrum having a maximum between 430 nm and 550 nm inclusive, especially between 470 nm and 510 nm inclusive.

The properties with regard to the first radiation-emitting component have already been disclosed in relation to the radiation-emitting component and are likewise applicable to the radiation-emitting component present in the light source. The light source is thus of particularly good suitability for illumination in the evening hours, since it has a greatly reduced MDEF with simultaneously unchanged color temperature, high color quality and very high luminous efficacy of radiation.

In at least one embodiment, the second luminophore has an emission spectrum having an emission maximum having a half-height width between 1 nm and 10 nm inclusive, especially between 1 nm and 5 nm inclusive.

In at least one embodiment, the first luminophore is selected from (Y, Lu) ₃Al₅O₁₂ : Ce, Y₃ (Al, Ga) ₅O₁₂ : Ce and combinations thereof. These first luminophores can be excited particularly efficiently with short-wave blue-emitting semiconductor chips, especially in the range of 448 nm to 450 nm.

In at least one embodiment, the light source also includes a second radiation-emitting component including
a semiconductor chip which, in operation, emits electromagnetic radiation in a first wavelength range in the blue spectral region, and
a conversion element having a third luminophore that converts electromagnetic radiation in the first wavelength range to electromagnetic radiation in a second wavelength range in the green spectral region,and having a fourth luminophore that converts electromagnetic radiation in the first wavelength range to electromagnetic radiation in a third wavelength range in the red spectral region,
wherein the fourth luminophore has an excitation spectrum having a maximum at shorter wavelengths than the maximum of the excitation spectrum of the second luminophore.

The second radiation-emitting component, in one embodiment, has the same semiconductor chip as the above-described first radiation-emitting component with greatly reduced MDEF. In addition, the third luminophore, in one embodiment, may be the same luminophore as the first luminophore. The fourth luminophore may, for example, be KSF.

Thus, in one light source, it is possible to combine a radiation-emitting component as described above having greatly reduced MDEF with a second radiation-emitting component having nonreduced MDEF, which allows the light source to be utilized irrespective of the time of day without unfavorably affecting the production of melatonin.

In at least one embodiment, the first and second radiation-emitting components are drivable independently of one another. It is thus possible, according to the time of day, to establish the desired MDEF in an infinitely variable manner within a light source without altering the white point or color temperature or color rendering index of the radiation emitted.

Also specified is a display device including a radiation-emitting component. The radiation-emitting component, according to the abovementioned embodiments, may be suitable and intended for use in a display device as described here. Features and embodiments that have been detailed merely in conjunction with the radiation-emitting component are also applicable to the display device, and vice versa.

In at least one embodiment, the display device includes a radiation-emitting component comprising
a semiconductor chip which, in operation, emits electromagnetic radiation in a first wavelength range in the blue spectral region, and
a conversion element having a first luminophore that converts electromagnetic radiation in the first wavelength range to electromagnetic radiation in a second wavelength range in the green spectral region,
and having a second luminophore that converts at least electromagnetic radiation in the first wavelength range to electromagnetic radiation in a third wavelength range in the red spectral region,
wherein the second luminophore has an excitation spectrum having a maximum between 430 nm and 550 nm inclusive, especially between 470 nm and 510 nm inclusive,
further including at least one color filter.

The radiation-emitting component thus serves as display backlighting, in which case the light emitted by the radiation-emitting component is separated by means of color filters into different color channels, especially a green color channel, a red color channel and a blue color channel, per pixel. The second luminophore present in the conversion element of the radiation-emitting component serves here as an additional filter for the light with wavelengths in the blue-green and/or cyan region, so as to reduce crosstalk between the color channels and simultaneously to achieve a large color space.

In at least one embodiment, the second luminophore has an emission spectrum having an emission maximum having a half-height width between 1 nm and 10 nm inclusive, especially between 1 nm and 5 nm inclusive.

### BRIEF DESCRIPTION OF THE DRAWINGS

Further advantageous embodiments, configurations and developments of the radiation-emitting component, of the light source and of the display device will be apparent from the working examples which follow, presented in conjunction with the figures.

FIG. 1 shows a schematic section view of a radiation-emitting component in one working example.

FIG. 2A shows a plot of the melanopic activity function, alone, of a second luminophore; and FIG. 2B shows the melanopic activity function by comparison with the absorption spectrum of the second luminophore in one example.

FIGS. 3A and 3B show simulated emission spectra of radiation-emitting components with conversion element according to working examples and comparative examples by comparison with the melanopic activity function.

FIG. 4 shows a schematic section view of a display device in one working example.

FIG. 5A shows a simulation of the dependence of the color space overlap achieved in a radiation-emitting component in a comparative example on the peak wavelength of β-sialon emission; and FIG. 5B shows the same correlation as a function of CIE coordinates CIE x and CIE y.

FIG. 6A shows a simulation of the dependence of the color space overlap achieved in a radiation-emitting component in a comparative example in a working example on the peak wavelength of β-sialon emission; and FIG. 6B shows the correlation of FIG. 6A as a function of the CIE coordinates CIE x and CIE y.

FIG. 7 shows the luminous efficacy of radiation of a radiation-emitting component in a working example and in a comparative example as a function of the peak wavelength of β-sialon emission.

FIG. 8 shows a simulated emission spectrum of a radiation-emitting component in one embodiment.

Elements that are the same, of the same type or have the same effect are given the same reference numerals in the figures. The figures and the size ratios of the elements shown in the figures should not be considered to be true to scale with respect to one another. Instead, individual elements, especially layer thicknesses, may be shown in excessively large size for better representability and/or for better understanding.

### DETAILED DESCRIPTION

FIG. 1 shows a schematic section view of a radiation-emitting component 100 in one working example. This may be present, for example, in a light source. The radiation-emitting component 100 contains a housing 30 having a depression in which there are disposed a semiconductor chip 10 and, atop the semiconductor chip 10, a conversion element 20. Also present in the depression is an encapsulant 40 that surrounds the semiconductor chip 10 and the conversion element 20. The conversion element 20 is disposed in the beam path of the semiconductor chip 10, such that it can convert primary radiation emitted by the semiconductor chip 10 at least partly to a secondary radiation. In this working example, the conversion element 20 is disposed directly atop the semiconductor chip 10, but it may also be arranged at a distance from the semiconductor chip 10, for example on an adhesive layer (not shown here), or on the side of the encapsulant 40 remote from the semiconductor chip 10. Alternatively, the conversion element 20 may also be part of the encapsulant 40 or form the encapsulant 40 (not shown here).

The semiconductor chip 10 is especially an LED chip.

The semiconductor chip 10 emits electronic radiation in a first wavelength range in the blue spectral region. In particular, the radiation emitted by the semiconductor chip 10 has an emission spectrum having a dominant wavelength of not more than 460 nm, especially not more than 455 mm, or having a peak wavelength of not more than 450 nm.

The conversion element 20 contains a first luminophore that converts electromagnetic radiation in the first wavelength range to electrolytic radiation in a second wavelength range in the green spectral region, and a second luminophore that converts at least electromagnetic radiation in the first wavelength range to electromagnetic radiation in a third wavelength range in the red spectral region. The conversion element 20 may also contain a matrix material in which first and second luminophores are embedded.

The first luminophore has an excitation maximum in the region of the first wavelength range. For example, the first luminophore is a modified garnet such as (Y,Lu)₃Al₃O₁₂:Ce having an excitation maximum at 448 nm to 450 nm. Another alternative is Y₃ (Al, Ga) ₅O₁₂:Ce, which has a similar excitation maximum. Such a first luminophore is especially used when the radiation-emitting component 100 is present in a light source that is to have a minor melanopic effect on the human body.

Alternatively, the first luminophore may also be a β-sialon, especially a modified β-sialon having particularly short-wave emission, for example a β-sialon having the formula Si₆₋ₖAlₖOₖN₈₋ ₖ:Eu with 0 < k ≤ 0.45, such as 0.001 ≤ k ≤ 0.40 (or 0.002 ≤ k ≤ 0.35). First luminophores composed of other material systems having particularly narrowband emission, i.e. a half-height width of less than 50 nm, especially less than 45 nm, are likewise suitable. Such first luminophores may especially be used when the radiation-emitting component 100 is being used as display backlighting in a display device 200, since they can be used to define a color triangle of maximum size for the filtered green color channel.

The second luminophore has an excitation spectrum comprising a maximum between 430 nm and 550 nm inclusive, especially between 470 nm and 510 nm inclusive. This means that it has long-wave absorption and excitability. In addition, the second luminophore has an emission spectrum having an emission maximum having a half-height width between 1 nm and 10 nm inclusive, especially between 1 nm and 5 nm inclusive, i.e. a low half-height width, especially a line emission. Thus, the second luminophore has a high LER. In particular, the second luminophore is selected from CaHfF₆:Mn, CaZrF₆:Mn, SrTiF₆:Mn, ZnHfF₆:Mn; for example, the second luminophore is CaHfF₆:Mn.

There follows an elucidation of working examples for the preparation of the second luminophore using the examples of CaHfF₆:Mn, CaZrF₆:Mn, SrTiF₆:Mn, ZnHfF₆:Mn.

### Preparation of the Second Luminophore According to the Working Example CaZrF₆:Mn

A stoichiometric composition of the reactants calcium fluoride (780.8 mg, 10 mmol), zirconyl chloride octahydrate (3.144 g, 9.8 mmol) and manganese(II) chloride tetrahydrate (39.5 mg, 0.2 mmol) is mixed intimately in an agate mortar and introduced into a corundum boat. This corundum boat is placed in a corundum tube heatable by a tubular furnace, through which 10% by volume of F₂ in argon is passed. The intermediate temperature is increased from 30° C. by 20° C. (0.33° C./minute), and this intermediate temperature is kept constant for one hour. The stepwise increase in the intermediate temperature and the hold times are repeated until 370° C. has been reached. The intermediate temperature is increased at 4° C./min to 400° C. within three days. After a hold time of a further five days, the reaction mixture is cooled down to a minimum temperature of 30° C., crushed in a glassy carbon dish, and placed back in the furnace. The furnace is heated up again to 400° C. at a heating rate of 4° C./min and, after two further days, the intermediate temperature is increased at 4° C./min to a maximum temperature of 450° C. and kept at that maximum temperature for one further day. Subsequently, the reaction mixture is taken out of the oven and cooled down, and the second luminophore having the formula CaZrF₆:Mn is obtained.

### Preparation of the Second Luminophore According to the Working Example CaHfF₆:Mn

A stoichiometric composition of the reactants calcium fluoride (78.3 mg, 1 mmol), hafnium(IV) oxide (199.9 mg, 0.95 mmol) and manganese (II) chloride tetrahydrate (9.6 mg, 0.05 mmol) is mixed intimately in an agate mortar and introduced into a corundum boat. This corundum boat is placed in a corundum tube heatable by a tubular furnace, through which 10% by volume of F₂ in argon is passed. The intermediate temperature is increased from 30° C. by 20° C. (0.33° C./minute), and this intermediate temperature is kept constant for one hour. The stepwise increase in the temperature and the hold times are repeated until 370° C. has been reached. The reaction mixture is cooled down to a minimum temperature of 30° C. after six days. Subsequently, the reaction mixture is taken out of the furnace and crushed in a glassy carbon dish and placed back in the furnace. The furnace is heated up again to 400° C. at a heating rate of 4° C./min and, after a further five days, the reaction mixture is cooled down to a minimum temperature of 30° C., crushed with a mortar and subjected to heat treatment at 450° C. for a further 14 days at 450° C. in a fluorine stream. The second luminophore having the formula CaHfF₆:Mn is obtained.

### Preparation of the Second Luminophore According to the Working Example SrTiF₆:Mn

A stoichiometric composition of the reactants strontium carbonate (590.3 mg, 4 mmol), titanium(IV) sulfide (443.0 mg, 3.96 mmol) and manganese(II) chloride tetrahydrate (10.3 mg, 0.04 mmol) is mixed intimately in an agate mortar and introduced into a corundum boat. This corundum boat is placed in a corundum tube heatable by a tubular furnace, through which 10 ml/min of 5% by volume of F₂ in argon is passed. The intermediate temperature is increased to 100° C. (5° C./h), and this intermediate temperature is kept constant for 20 hours. The stepwise increase in the intermediate temperature by 100° C. each time (10° C./h) and the hold times (10 hours) are repeated until 300° C. has been reached. After four days, the reaction mixture is cooled down to a minimum temperature of 30° C., and the reaction mixture is taken out of the furnace and crushed in a glassy carbon dish and placed back in the furnace. The furnace is heated again at a heating rate of 4° C./min to 300° C. and the reaction mixture is again reacted with a gas stream of 10 ml/min of 5% by volume of F₂ in argon for a further 10 days. The second luminophore having the formula SrTiF₆:Mn is obtained.

### Preparation of the Second Luminophore According to the Working Example ZnHfF₆:Mn

A stoichiometric composition of the reactants zinc chloride (135.1 mg, 1 mmol), hafnium(IV) oxide (200.5 mg, 0.95 mmol) and manganese(II) chloride tetrahydrate (11.8 mg, 0.05 mmol) is mixed intimately in an agate mortar and introduced into a corundum boat. This corundum boat is placed in a corundum tube heatable by a tubular furnace, through which 10% by volume of F₂ in argon is passed. The intermediate temperature is increased from 30° C. by 20° C. (0.33° C./minute), and this intermediate temperature is kept constant for one hour. The stepwise increase in the intermediate temperature and the hold times are repeated until 370° C. has been reached.

After a hold time of two days, the furnace is cooled down to a minimum temperature of 30° C., and the reaction mixture is taken out and crushed in a glassy carbon dish and placed back in the furnace. The furnace is heated up again to 400° C. at a heating rate of 4° C./min and the reaction mixture is fluorinated for a further four days, before it is cooled down again to 30° C. and crushed. The reaction mixture is put back in the furnace again and heated at 4° C./min to a maximum temperature of 450° C., and the reaction mixture is subjected to heat treatment in a fluorine stream for a further four days. The second luminophore having the formula ZnHfF₆:Mn is obtained.

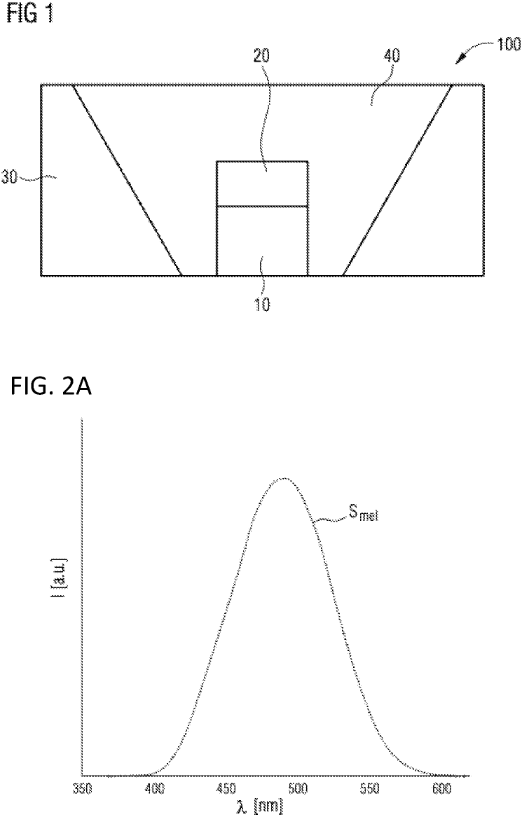

FIG. 2A shows a plot of the melanopic activity function sₘₑₗ. The wavelength λ in nm is plotted here against intensity I in arbitrary units. If a melanopically active component of a radiation is to be assessed, the overlap with the melanopic activity function sₘₑₗ is considered.

FIG. 2B shows the melanopic activity function sₘₑₗ by comparison with the excitation spectrum A1 of CaZrF₆:Mn. Here too, wavelength λ in nm is again plotted against intensity I in arbitrary units. The excitation spectrum A1 is measured at an emission wavelength of 628 nm. In the range from about 450 nm to 550 nm, a large overlap of excitation spectrum A1 and melanopic activity function sₘₑₗ is apparent, which is because of the marked absorption band of CaZrF₆:Mn in the region of 490 nm. Thus, if CaZrF₆:Mn is used as second luminophore in a radiation-emitting component 100, it efficiently absorbs spectral components in exactly that wavelength range which has a particularly large melanopic effect. This region covers emitted radiation from the semiconductor chip 10, and the blue-green and/or cyan component of the radiation converted by the first luminophore.

By comparison, the comparative luminophore KSF, which likewise emits in the red spectral region, is excitable at wavelengths of about 450 nm, while absorption in the region of 490 nm is low. This means that the luminophore KSF absorbs the blue-green and/or cyan components of the radiation emitted by the semiconductor chip 10 and of the radiation emitted by the first luminophore only to a small degree, if at all. As a result, a radiation-emitting component with such a red light-emitting comparative luminophore has a high proportion of radiation in the blue-green or cyan spectral region and hence has a very large melanopic effect. Such a radiation-emitting component having a second comparative luminophore can be combined in a light source with a radiation-emitting component 100 in one working example. If the two components can be driven independently of one another, infinite variability of the MDEF is thus possible without any change in color temperature or color rendering index.

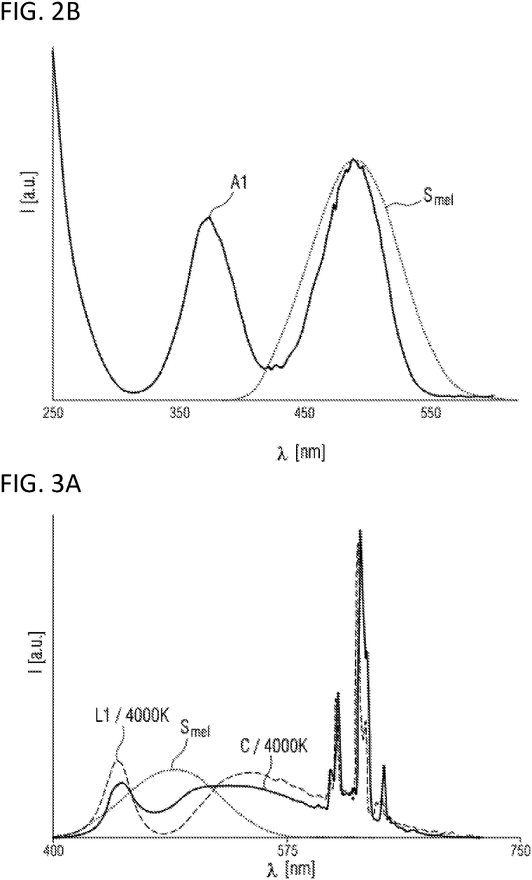

FIGS. 3A and 3B show simulated emission spectra of radiation-emitting components that still further illustrate the properties mentioned. Here too, wavelength λ in nm is again plotted in each case against intensity I in arbitrary units. In both spectra, for comparison, the melanopic activity function sₘₑₗ is plotted by way of comparison in order to visualize the spectral differences in the relevant range from 450 nm to 550 nm.

FIG. 3A shows the simulated spectrum L1/4000K of a working example of a radiation-emitting component 100 with a semiconductor chip 10, the dominant wavelength λ_{dom} of which is 455 nm, and a conversion element 20 containing Lu₃Al₅O₁₂:Ce as first luminophore and CaZrF₆:Mn as second luminophore, at a color temperature CCT of 4000 K. Additionally shown is the spectrum C/4000K of a comparative example containing KSF in place of CaZrF₆:Mn as second luminophore.

It can be inferred or calculated from the simulated spectra L1/4000K and C/4000K that both the working example and the comparative example have a comparable color rendering index CRI of about 83 to 84, but the radiation-emitting component according to the working example has an elevated R9 value of 81 in comparison to 25 in the comparative example. In addition, the radiation-emitting component according to the working example has a significantly reduced MDEF value of only 0.544 rather than 0.733 in the comparative example, which means a reduction by 26%. At the same time, the working example has a higher LER value of 341 lm/W rather than 314 lm/W in the comparative example, which means an increase by 9%.

FIG. 3B shows the simulated spectrum L1/3000K of the working example as described in relation to FIG. 3A, but at a color temperature CCT of 3000 K. Also shown is the spectrum C/3000K of the comparative example, likewise at a color temperature of 3000 K.

It can be inferred or calculated from the simulated spectra L1/3000K and C/3000K that the color rendering index CRI and the R9 value of the working example are elevated compared to the comparative example. In addition, the radiation-emitting component 100 according to the working example has a significantly reduced MDEF value of only 0.423 rather than 0.581 in the comparative example, which means a reduction by 27%. At the same time, the working example has a higher LER value of 344 lm/W rather than 318 lm/W in the comparative example, which means an increase by 8%.

Table 1 shows the results from FIGS. 3A and 3B once again as overview. The first luminophore here is named “G”, the second luminophore “R”. The dominant wavelength of the semiconductor chip 10 is identified in the table as λ_{dom}(B). In addition, the table also lists the values of the coordinates CIE x and CIE y.

TABLE 1

| | C/4000K | L1/4000K | C/3000K | L1/3000K |
|---|---|---|---|---|
| λ_{dom} (B) [nm] | 456 | 455 | 455 | 455 |
| G | Lu₃Al₅O₁₂:Ce | Lu₃Al₅O₁₂:Ce | Lu₃Al₅O₁₂:Ce | Lu₃Al₅O₁₂:Ce |
| R | K₂SiF₆:Mn | CaZrF₆:Mn | K₂Sif₆:Mn | CaZrF₆:Mn |
| CIE x | 0.381 | 0.380 | 0.436 | 6.437 |
| CIE y | 0.376 | 0.376 | 0.404 | 0.464 |
| CRI | 83 | 84 | 75 | 88 |
| R9 | 25 | 81 | 19 | 95 |
| MDEF | 0.733 | 0.544 | 0.681 | 0.423 |
| LER (lm/W) | 314 | 341 | 318 | 344 |

It can thus be concluded from FIGS. 3A and 3B that the combination of semiconductor chip 10, a conversion element 20 having first and second luminophores having the above-described advantageous properties, as compared with a combination of semiconductor chip 10, first luminophore and comparative luminophore with the same CCT, can in each case achieve a significant reduction in the MDEF value combined with good color rendering and high LER. For instance, the MDEF of the comparative example even at the lower color temperature of 3000 K is still higher than the MDEF according to the working example at a higher color temperature of 4000 K. For example, it is possible to achieve a comparatively neutral white illumination at 4000 K that has a reduced MDEF compared to a distinctly warmer white illumination at 3000 K according to the comparative example.

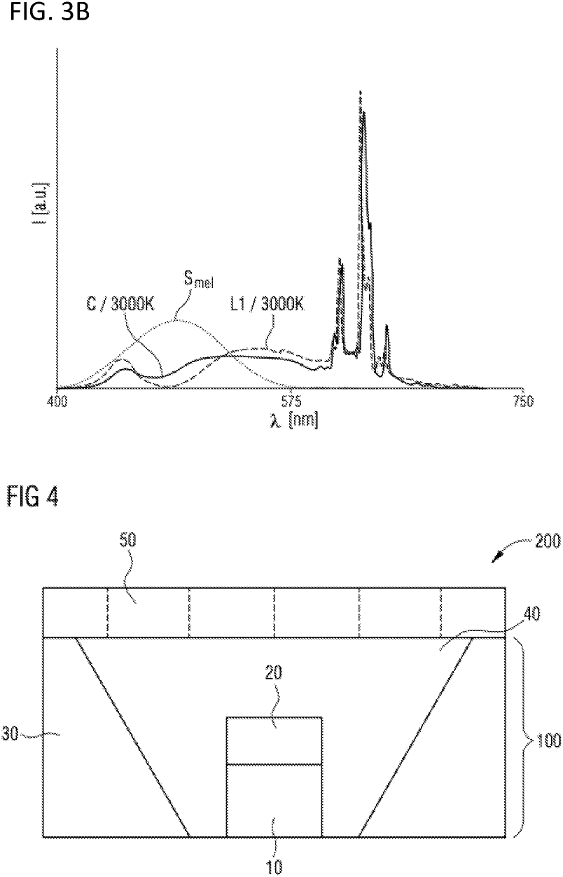

FIG. 4 shows a section view of a display device 200 according to a working example. The display device 200 contains a radiation-emitting component 100 as already described in relation to FIG. 1. In addition, the display device 200 comprises color filters 50 that separate the white light emitted by the radiation-emitting component 100 into the color channels of red, green and blue for the respective pixels of the display device 200. The color channels are indicated by the dotted lines.

Radiation-emitting components used in conventional display devices are blue light-emitting semiconductor chips that are combined with conversion elements containing β-sialon:Eu²⁺ as green light-emitting first luminophore and KSF as red light-emitting second luminophore. The shorter-wave the emission of the first luminophore, the greater the extent to which the color locus of the filtered green color channel can be shifted in the direction of a lower dominant wavelength, i.e. less yellowish green. Crosstalk of the luminophore emission from one color channel into an adjacent color channel is not to take place here. A first luminophore emitting green light of excessive spectral breadth or excessively shifted in the direction of short-wave emission can make emission contributions in the emission spectrum of the radiation-emitting component that are in the transmission region of the blue color channel. As a result, the color locus of the blue color channel can be shifted in the cyan direction, which in turn reduces the overall gamut of colors that can be presented.

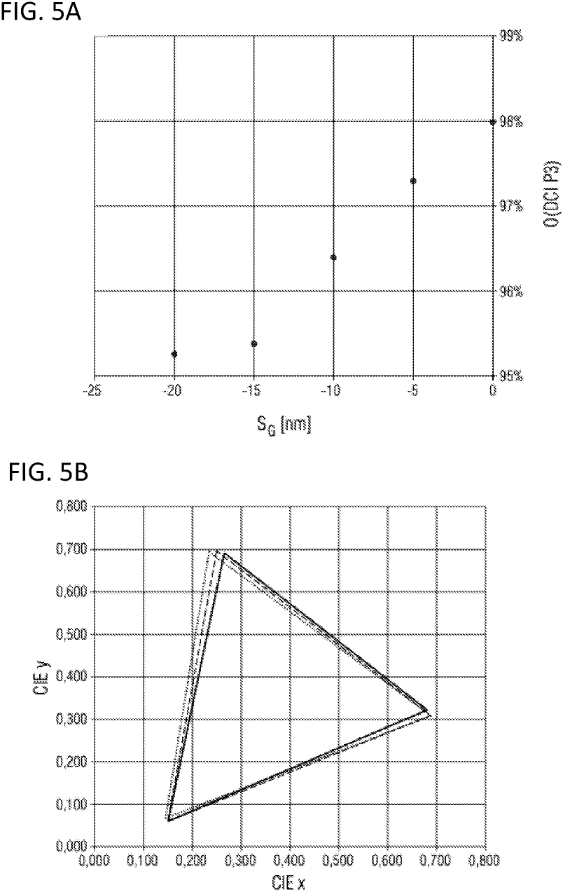

This effect is illustrated in FIGS. 5A and 5B. FIG. 5A shows a simulation of the dependence of the color space overlap achieved, 0 (DCI P3) (in %), in a radiation-emitting component in a comparative example with the color space DCI P3 of the spectral shift S_{G} in nm of the peak wavelength of β-sialon. In the comparative example, a blue light-emitting semiconductor chip 10 is combined with the luminophores β-sialon and KSF. The wavelength emitted by the semiconductor chip 10 and by the KSF and the overall color locus of the radiation-emitting component, and also the filter curves were kept constant in all cases. It is apparent that a short-wave shift in the peak wavelength of β-sialon leads to a reduction in overlap with the DCI P3 color space.

FIG. 5B shows this correlation once again as a function of the CIE coordinates CIE x and CIE y. The DCI P3 color space is shown by a solid line. The color space which is achieved with an unshifted β-sialon (S_{G} = 0 nm) is shown by the dotted line, and the color space achieved with a β-sialon with a shift S_{G} = 20 nm by a dotted line. It is apparent that the short-wave shift in the peak wavelength of β-sialon does not lead to better presentation of the green shades. Moreover, there is also a shift in the color locus of the filtered blue color channel in the cyan direction, such that representability of blue shades is also less good.

By contrast, it is actually possible to achieve elevated color space coverage with a radiation-emitting component 100 according to a working example that contains an above-described luminophore, for example CaZrF₆:Mn, as second luminophore, with a short-wave shift S_{G} in the peak wavelength of the first luminophore β-sialon.

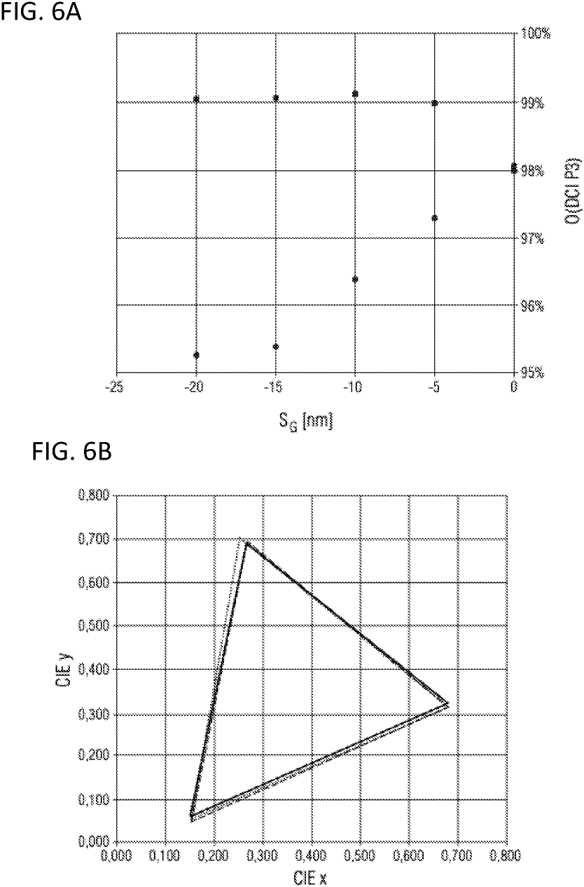

This is shown, for example, in FIG. 6A. This corresponds essentially to FIG. 5A, except that the values for a radiation-emitting component 100 according to a working example are also shown here (represented by black squares). The working example and the comparative example (represented by black circles) differ merely by their second luminophore, which is KSF in the comparative example and CaZrF₆:Mn in the working example. Here too, the emission wavelength of the semiconductor chip 10, the emission of the second luminophore and the color locus of the radiation-emitting component 100, and also the filter curves were kept constant.

The improvement in color space coverage which is apparent from FIG. 6A can be attributed to higher color purity in the filtered green color channel. There is also no shift in the filtered blue color channel in the cyan direction.

FIG. 6b shows the correlation of FIG. 6A once again as a function of the CIE coordinates CIE x and CIE y. The solid line describes the DCI P3 color space, the dashed line the color space of the unshifted working example (S_{G} = 0 nm), and the dotted line the color space of the working example with a shift S_{G} of 20 nm. It is apparent that there is actually an enlargement of the color space as a result of the shift S_{G} compared to DCI P3.

The positive effect of the working example is attributable to the specific combination of properties of the second luminophore used in combination with the first luminophore used and the semiconductor chip 10 used. Spectral components in the range from about 470 nm to 510 nm that would cause crosstalk of the blue color channel into the green color channel or crosstalk of the green color channel into the blue color channel are absorbed by the second luminophore and converted to red light. The color locus of the emission of the second luminophore is advantageously chosen so as to achieve high color purity in the filtered red color channel as well.

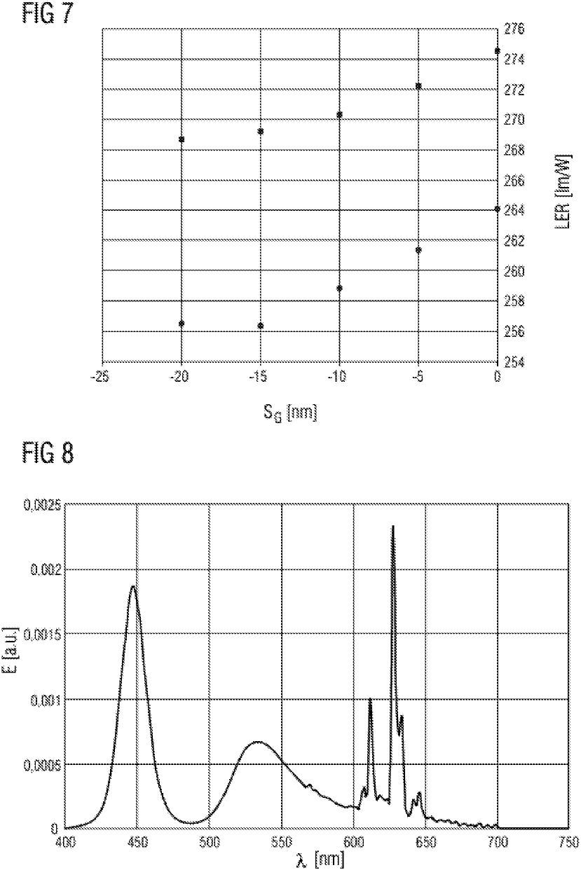

FIG. 7 shows the dependence of the luminous efficacy of radiation LER in lm/W of the emitted spectrum of the radiation-emitting component 100 on the shift S_{G} in nm of the peak wavelength of the first luminophore. The black squares are the values for the working example with CaZrF₆:Mn as the second luminophore; the black circles are the values for the comparative example with KSF as the second luminophore. The emission from semiconductor chip 10 and from the second luminophore and the overall color locus of the radiation-emitting component 100, and also the filter curves were kept constant. It is apparent that a short-wave shift in the emission of the first luminophore β-sialon also affects luminous efficacy, with higher luminous efficacy in the working example in each case. The above-described positive effects on color space coverage are thus associated with an increase in luminous efficacy LER of the radiation-emitting component 100.

Table 2 additionally shows color locus coordinates ascertained for various spectra/combinations of luminophores after filtering, the overlap 0 with the respective color space coordinates as a function of the shift S_{G} for the working example with a semiconductor chip having a dominant wavelength λ_{dom}(B) of 455 nm, a β-sialon as first luminophore (G) and CaZrF₆:Mn as second luminophore (R), and the comparative example with a semiconductor chip having a dominant wavelength λ_{dom}(B)of 455 nm, a β-sialon as first luminophore (G) and with KSF as second luminophore (R). For the simulation, all spectra were set to CIE x = 0.278 and CIE y = 0.260 (before filtering). In order to ascertain the overlap O, standard color filter curves for high-color-gamut displays were applied to the spectra, and the filtered color locus coordinates of the respective colors (R_{f}, B_{f} and Gf) were ascertained. Finally, the respective luminous efficacy of radiation LER is also reported in table 2.

TABLE 2

| | | | | | | | | | | | |
|---|---|---|---|---|---|---|---|---|---|---|---|
| | λ_{dom} (B) [nm] | 455 | 455 | 455 | 455 | 455 | 455 | 455 | 455 | 455 | 455 |
| | G | β-Sialon | β-Sialon | β Sialon | β-Sialon | β-Sialon | β-Sialon | β-Sialon | β-Sialon | β-Sialon | β-Sialon |
| | S₀ [nm] | 0 | -6 | -10 | -15 | -20 | 0 | -5 | -10 | -15 | -20 |
| | H | KSF | KSF | KSF | KSF | KSF | CaZrFa Mn | CaZrFa Mn | CaZrFa Mn | CaZnFa Mn | CaZrFa Mn |
| O (sRGB) | xy | 100.0 % | 100.0 % | 99.9% | 99.7% | 99.7% | 99.9% | 99.9% | 99.9% | 100.0% | 100.0% |
| O (NTSC) | xy | 89.3% | 90.7% | 91.8% | 92.6% | 32.6% | 84.9% | 86.3% | 87.4% | 88.2% | 88.3% |
| O (Adobe) | xy | 81.6% | 93.1% | 94.3% | 95.2% | 95.3% | 88.8% | 88.3% | 89.5% | 90.3% | 95.4% |
| O (DCI-P3) | xy | 98.0% | 97.3% | 86.4% | 95.4% | 95.3% | 98.0% | 99.0% | 99.1% | 99.1% | 99.0% |
| O(rec2020) | xy | 74.7% | 75.1% | 75.2% | 75.1% | 75.0% | 73.2% | 74.0% | 74.6% | 74.9% | 74.9% |
| O (sRGB) | uv | 100.0% | 99.9% | 99.5% | 98.9% | 98.7% | 99.4% | 99.6% | 99.7% | 99.8% | 99.8% |
| O (NTSC) | uV | 92.4% | 93.3% | 94.2% | 94.8% | 94.9% | 88.6% | 89.6% | 90.3% | 90.9% | 90.9% |
| O (Adobe) | uV | 96.4% | 97.3% | 97.7% | 97.8% | 97.7% | 92.0% | 99.0% | 93.9% | 94.5% | 94.6% |
| O (DCI-P3) | uV | 99.1% | 95.6% | 97.5% | 96.3% | 96.1% | 97.6% | 98.4% | 98.8% | 90.0% | 99.9% |
| O (rec202 0) | uV | 77.7% | 77.3% | 76.7% | 76.0% | 75.9% | 77.7% | 78.1% | 78.2% | 78.0% | 78.0% |
| R_{f} | × | 0.665 | 0.686 | 0.687 | 0.687 | 0.687 | 0.680 | 0.681 | 0.681 | 0.682 | 0.682 |
| | y | 0.308 | 0.308 | 0.307 | 0.307 | 0.307 | 0.313 | 0.312 | 0.311 | 0.311 | 0.311 |
| | u ' | 0.515 | 0.518 | 9.517 | 0.517 | 0.517 | 0.504 | 0.506 | 0.507 | 0.507 | 0.507 |
| | v ' | 0.521 | 0.920 | 0.520 | 0.820 | 0.520 | 0.622 | 0.522 | 0.522 | 0.522 | 0.621 |
| G_{f} | x | 0.251 | 2.244 | 0.239 | 6.234 | 0.234 | 0.268 | 0.261 | 0.256 | 0.263 | 0.253 |
| | y | 0.695 | 0.696. | 0.695 | 0.963 | 0.683 | 0.596 | 0.700 | 0.762 | 0.708 | 0.792 |
| | u′ | 0.093 | 0.090 | 6.055 | 0.089 | 0.088 | 0.099 | 0.698 | 0.094 | 0.093 | 0.093 |
| | v | 0.577 | 0.577 | S..S76 | 6.578 | 9.675 | 0.57′9 | 0.8711 | 0.570 | 0.879 | 0.579 |
| E_{f} | x | 0.148 | 0.147 | 0.146 | 0.145 | 0.145 | 0.154 | 0.153 | 0.153 | 0.152 | 0.1 52 |
| | y | 0.058 | 0.081 | 0.084 | 0.666 | 0.007 | 0.045 | 0.061 | 0.953 | 0.064 | 0.054 |
| | u | 0.174 | 0.171 | 0.165 | 0.168 | 0.165 | 0.188 | 0.188 | 0.184 | 0.182 | 0.182 |
| | v ' | 0.154 | 0.160 | 0.165 | 0.170 | 0.171 | 0.134 | 0.138 | 0.142 | 0.146 | 0.146 |
| LER (lm/W) | | 264 | 261 | 259 | 256 | 257 | 275 | 272 | 270 | 269 | 269 |

FIG. 8 shows the simulated emission spectrum of the working example with a semiconductor chip having a dominant wavelength λ_{dom}(B)of 455 nm, a β-sialon as first luminophore and CaZrF₆:Mn as second luminophore with the color locus CIE x = 0.278 and CIE y = 0.260.

The features and working examples described in conjunction with the figures may be combined with one another in further working examples, even if not all combinations are described explicitly. In addition, the working examples described in conjunction with the figures may alternatively or additionally have further features according to the description in the general part.

The invention is not limited to the working examples by the description with reference thereto. Instead, the invention encompasses any new feature and any combination of features, which especially include any combination of features in the patent claims, even if this feature or this combination itself is not explicitly specified in the patent claims or working examples.

### List of Reference Numerals

10 semiconductor chip
20 conversion element
30 housing
40 encapsulant
50 color filter
100 radiation-emitting component
200 display device
Sₘₑₗ melanopic activity function
A1 excitation spectrum of CaZrF₆:Mn
L1/4000K emission spectrum of a radiation-emitting component in a working example
C/4000K emission spectrum of a radiation-emitting component in a comparative example
L1/3000K emission spectrum of a radiation-emitting component in a working example
C/3000K emission spectrum of a radiation-emitting component in a comparative example

1. A radiation-emitting component comprising_
a semiconductor chip configured to emit electromagnetic radiation in a first wavelength range in the blue spectral region; and
a conversion element comprising:
a first luminophore configured to emit electromagnetic radiation in the first wavelength range to electromagnetic radiation in a second wavelength range in the green spectral region; and
a second luminophore configured to convert at least electromagnetic radiation in the first wavelength range to electromagnetic radiation of a third wavelength range in the red spectral region;
wherein the second luminophore has an excitation spectrum having a maximum ranging from 430 nm to 550 nm inclusive.

2. The radiation-emitting component as claimed in the claim 1, wherein the second luminophore has an emission spectrum having an emission maximum having a half-height width ranging from 1 nm to 10 nm inclusive.

3. The radiation-emitting component as claimed in claim wherein the excitation spectrum of the second luminophore has a maximum ranging from 470 nm to 510 nm inclusive.

4. The radiation-emitting component as claimed in claim 1, wherein the emission maximum of the second luminophore ranges from 620 nm to 635 nm inclusive.

5. The radiation-emitting component as claimed in claim 1, wherein the second luminophore is configured to at least partly convert electromagnetic radiation in the second wavelength range to electromagnetic radiation in the third wavelength range.

6. The radiation-emitting component as claimed in claim 1, wherein the second luminophore has the general formula A_{Z}EₑX₆:RE where:
A is selected from the group of divalent elements,
E is selected from the group of tetravalent elements,
X is selected from the group of monovalent elements,
RE is selected from activated elements,
0.9 ≤ z ≤ 1.1, and
0.9 ≤ e ≤ 1.1.

7. The radiation-emitting component as claimed in claim 6, wherein:
A is selected from Ca, Sr, Ba, Zn, Mg, or combinations thereof,
E is selected from Hf, Ti, Zr, Pb, or combinations thereof,
X is selected from F, Cl, Br, I, or combinations thereof, and
RE is selected from Mn, Cr, Ni, or combinations thereof.

8. (canceled)

9. The radiation-emitting component as claimed in claim 1, wherein the semiconductor chip has an emission spectrum having a dominant wavelength λ_{dom} of not more than 460 nm.

10. The radiation-emitting component as claimed in claim 1, wherein the first luminophore has an excitation spectrum having a maximum ranging from 445 nm to 455 nm inclusive.

11. The radiation-emitting component as claimed in claim 1, wherein the first luminophore has an emission spectrum ranging from 500 nm to 580 nm.

12. The radiation-emitting component as claimed in claim 11, wherein an emission peak in the emission spectrum of the first luminophore has a half-height width of not more than 50 nm.

13. The radiation-emitting component as claimed in claim 1, wherein the first luminophore is selected from garnets, β-sialons, orthosilicates, and combinations thereof.

14. A light source comprising the first radiation-emitting component of claim 1.

15. The light source as claimed in claim 14, wherein the second luminophore has an emission spectrum having an emission maximum having a half-height width ranging from 1 nm to 10 nm inclusive.

16. The light source as claimed in claim 14, wherein the first luminophore is selected from (Y,Lu)₃Al₅O₁₂:Ce, Y₃(Al,Ga)₅O₁₂:Ce, and combinations thereof.

17. The light source as claimed in claim 14, further comprising a second radiation-emitting component, wherein the second radiation-emitting component comprises:
a second semiconductor chip configured to emit electromagnetic radiation in the first wavelength range in the blue spectral region; and
a second conversion element comprising:
a third luminophore configured to convert electromagnetic radiation in the first wavelength range to electromagnetic radiation in the second wavelength range in the green spectral region; and having
a fourth luminophore configured to convert electromagnetic radiation in the first wavelength range to electromagnetic radiation in the third wavelength range in the red spectral region;
wherein the fourth luminophore has an excitation spectrum having a maximum at shorter wavelengths than the maximum of the excitation spectrum of the second luminophore.

18. The light source as claimed in claim 17, wherein the first and second radiation-emitting components are drivable independently of one another.

19. A display device including a radiation-emitting component; wherein the display device comprises:
a semiconductor chip configured to emit electromagnetic radiation in a first wavelength range in the blue spectral region; and
a conversion element comprising:
a first luminophore configured to emit electromagnetic radiation in the first wavelength range to electromagnetic radiation in a second wavelength range in the green spectral region; and
a second luminophore configured to convert at least electromagnetic radiation in the first wavelength range to electromagnetic radiation in a third wavelength range in the red spectral region; wherein the
second luminophore has an excitation spectrum having a maximum ranging from 430 nm to 550 nm inclusive; and
at least one color filter.

20. The display device as claimed in claim 19, wherein the second luminophore has an emission spectrum having an emission maximum having a half-height width ranging from 1 nm to 10 nm inclusive.

21. A radiation-emitting component comprising:
a semiconductor chip configured to emit electromagnetic radiation in a first wavelength range in the blue spectral region; and
a conversion element comprising:
a first luminophore configured to convert electromagnetic radiation in the first wavelength range to electromagnetic radiation in a second wavelength range in the green spectral region; and
a second luminophore configured to convert at least electromagnetic radiation in the first wavelength range to electromagnetic radiation in a third wavelength range in the red spectral region; wherein the second luminophore has an excitation spectrum having a maximum ranging from 470 nm to 510 nm inclusive; and wherein the second luminophore is selected from CaHfF₆:Mn, CaZrF₆:Mn, SrTiF₆:Mn, ZnHfF₆:Mn, and combinations thereof.
